(19) United States
(12) Patent Application Publication
(10) Pub. No.: US 2013/0069489 A1
(43) Pub. Date: Mar. 21, 2013

(54) PIEZOELECTRIC DEVICE

(71) Applicant: SHUICHI MIZUSAWA, SAITAMA (JP)

(72) Inventor: SHUICHI MIZUSAWA, SAITAMA (JP)

(73) Assignee: NIHON DEMPA KOGYO CO., LTD., TOKYO (JP)

(21) Appl. No.: 13/606,021

(22) Filed: Sep. 7, 2012

(30) Foreign Application Priority Data
Sep. 20, 2011 (JP) 2011-204510

(51) Int. Cl. H01L 41/053

(52) U.S. Cl. 310/348

(57) ABSTRACT

Disclosed is a piezoelectric device mounted on a mount board, including: a piezoelectric vibrating piece having an excitation electrode and an extraction electrode extracted from the excitation electrode; and a base plate made of an insulative material, the base plate having a first face where the piezoelectric vibrating piece is placed and a second face opposite to the first face, where an external electrode is provided, wherein at least a part of an area other than the external electrode of the second face is hollowed to the first face side to form a cavity in the second face side for the mount board when the piezoelectric device is mounted on the mount board.

### CROSS-REFERENCE TO RELATED APPLICATIONS

This application claims the priority benefit of Japan application serial no. 2011-204510, filed on Sep. 20, 2011. The entirety of the above-mentioned patent application is hereby incorporated by reference herein and made a part of this specification.

### FIELD

This disclosure relates to a piezoelectric device capable of decreasing a stray capacitance generated from a mount board.

### DESCRIPTION OF THE RELATED ART

There is known a piezoelectric vibrating piece which is formed of a piezoelectric material and vibrates with a predetermined frequency. In such a piezoelectric vibrating piece, a piezoelectric device is formed between a lid plate and a base plate and is mounted on a mount board such as a print board for use. In recent years, as the piezoelectric device is miniaturized, a distance between an electrode formed in the piezoelectric device and a wiring electrode formed in the mount board is reduced, and a stray capacitance generated therebetween increases. Such a stray capacitance may reduce a variable frequency range of the piezoelectric device, which is problematic.

In this regard, for example, Japanese Patent Publication No. 2010-220140 discloses a piezoelectric oscillator having a shield electrode. The piezoelectric oscillator disclosed in Japanese Patent Publication No. 2010-220140 is provided with a shield electrode between the piezoelectric oscillator integrated circuit (IC) chip and the wiring pattern of the mount board to prevent generation of the stray capacitance between the IC chip and the wiring pattern of the mount board. In addition, the shield electrode is formed between layers of the ceramic package obtained by stacking a plurality of layers to prevent the shield electrode from making contact with other electrodes in the piezoelectric oscillator.

However, in the piezoelectric oscillator in which the shield electrode is formed disclosed in Japanese Patent Publication No. 2010-220140, it is necessary to additionally provide a ceramic layer, thereby increasing a size of the piezoelectric device. In addition, in the base plate made of a piezoelectric material, glass, or the like, it is difficult to form the shield electrode so as not to make contact with other electrodes in the piezoelectric device. Therefore, it is difficult to form the shield electrode.

A need thus exists for a piezoelectric device capable of decreasing a stray capacitance generated from the mount board by forming a hollow in the base plate between the wiring electrode of the mount board and the electrode formed in the piezoelectric device.

### SUMMARY

According to a first aspect of this disclosure, there is provided a piezoelectric device mounted on a mount board, including: a piezoelectric vibrating piece having an excitation electrode and an extraction electrode extracted from the excitation electrode; and a base plate made of an insulative material, the base plate having a first face where the piezoelectric vibrating piece is placed and a second face opposite to the first face, where an external electrode is provided, wherein at least a part of an area other than the external electrode of the second face is hollowed to the first face side to form a cavity in the second face side for the mount board when the piezoelectric device is mounted on the mount board.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is an exploded perspective view illustrating a piezoelectric device 100;

FIG. 2 is a cross-sectional view taken along a line II-II of FIG. 1;

FIG. 3A is a top plan view illustrating a base plate 120;

FIG. 3B is a cross-sectional view taken along a line IIIB-IIIB of FIG. 3A;

FIG. 4A is a top plan view illustrating a base plate 220;

FIG. 4B is a cross-sectional view taken along a line IVB-IVB of FIG. 4A;

FIG. 5A is a perspective view illustrating a base plate 320;

FIG. 5B is a top plan view illustrating the base plate 320;

FIG. 6A is a cross-sectional view taken along a line VIA-VIA of FIG. 5B;

FIG. 6B is a cross-sectional view taken along a line VIB-VIB of FIG. 5B;

FIG. 6C is a cross-sectional view taken along a line VIC-VIC of FIG. 5B;

FIG. 7 is an exploded perspective view illustrating a piezoelectric device 200;

FIG. 8A is a cross-sectional view taken along a line VIIIA-VIIIA of FIG. 7;

FIG. 8B is a top plan view illustrating a piezoelectric vibrating piece 430;

FIG. 9A is a top plan view illustrating a base plate 430; and

FIG. 9B is a cross-sectional view taken along a line IXB-IXB of FIG. 7.

### DETAILED DESCRIPTION

Hereinafter, embodiments of this disclosure will be described in detail with reference to the accompanying drawings, which are not intended to limit the scope of the invention unless specified otherwise.

### First Embodiment

<Configuration of Piezoelectric Device 100>

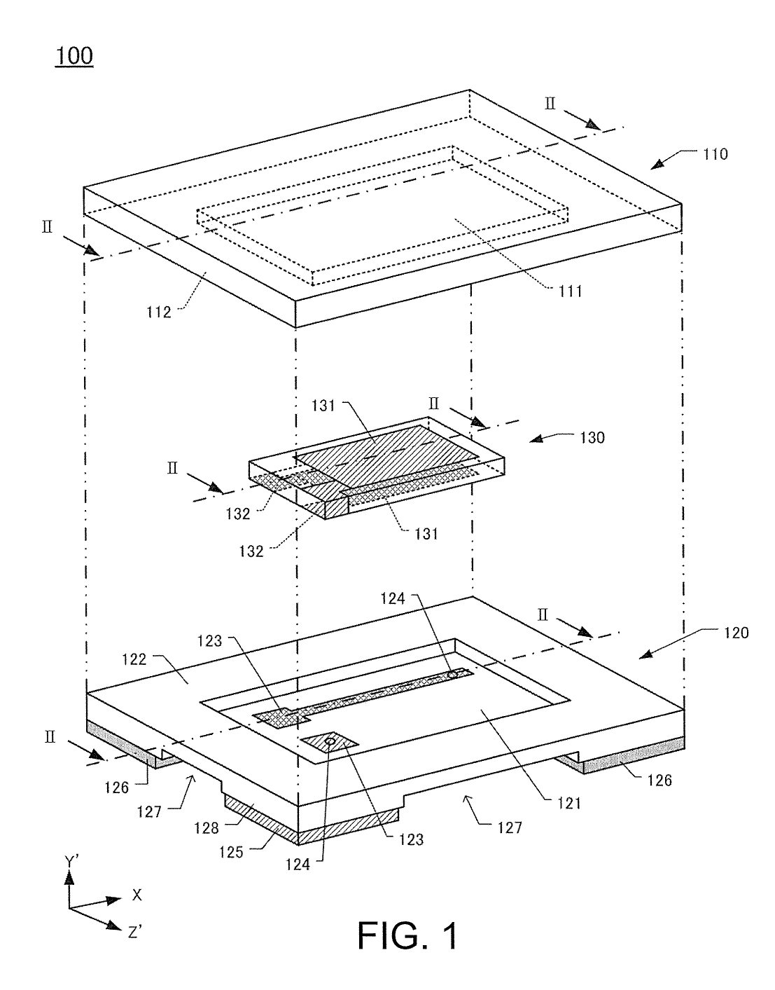

FIG. 1 is an exploded perspective view illustrating a piezoelectric device 100. The piezoelectric device 100 includes a piezoelectric vibrating piece 130, a lid plate 110, and a base plate 120. The base plate 120 is made of an insulative material such as ceramic, crystal, and glass. In addition, as the piezoelectric vibrating piece 130, for example, an AT-cut crystal vibrating piece is employed. The AT-cut crystal vibrating piece has a principal face (YZ plane) passing through the X-axis and inclined by 35° 15′ from the Z-axis in the Y-axis direction of the crystal axes in the XYZ coordinate system. In the follow description, the Y′-axis and Z′-axis inclined with respect to the axial direction of the AT-cut crystal vibrating piece are newly defined. Specifically, the longitudinal direction of the piezoelectric device 100 is defined as an X-axis direction, the height direction of the piezoelectric device 100 is defined as a Y′-axis direction, and a direction perpendicular to the X-axis and the Y′-axis is defined as a Z′-axis direction.

In the piezoelectric device 100, the piezoelectric vibrating piece 130 is placed on the hollow portion 121 formed in the +Y′-axis side of the base plate 120. In addition, the lid plate 110 is bonded to the +Y′-axis side face of the base plate 120 to provide the piezoelectric device 100 such that the hollow portion 121 having the piezoelectric vibrating piece 130 is encapsulated.

The piezoelectric vibrating piece 130 has the excitation electrodes 131 formed in the +Y′-axis side face and the −Y′-axis side face. The extraction electrode 132 extending in the −X-axis direction is extracted from the excitation electrode 131 of the +Y′-axis side through the lateral face of the +Z′-axis side to the −Y′-axis side face. In addition, the extraction electrode 132 is extracted from the excitation electrode 131 formed in the −Y′-axis side face to the −Z′-axis side corner of the −X-axis side.

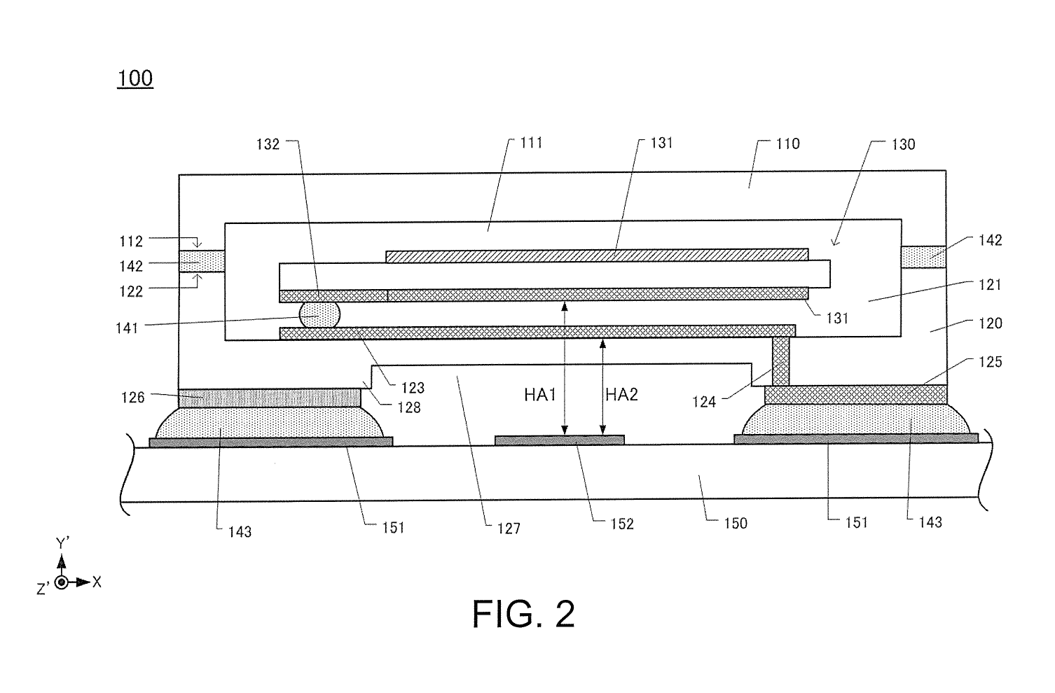

The base plate 120 has hollow portions in each of the +Y′-axis side face and the −Y′-axis side face. If the +Y′-axis side face is referred to as a first face, the first face has a hollow portion 121 where the piezoelectric vibrating piece 130 is placed, and a bonding face 122 bonded to the lid plate 110 using the encapsulating material 142 (refer to FIG. 2) is formed around the hollow portion 121. A connection electrode 123 bonded to the extraction electrode 132 of the piezoelectric vibrating piece 130 using the conductive adhesive 141 (refer to FIG. 2) is formed in the hollow portion 121. The connection electrode 123 is electrically connected to the mounting terminal 125 through the penetrating electrode 124. In addition, if the −Y′-axis side face is referred to as a second face, an external electrode is formed in the second face. The external electrode includes a mounting terminal 125 electrically connected to the excitation electrode 131 and the mount board such as a print board and a ground terminal 126 for removing static electricity charged in the piezoelectric device 100. Furthermore, a part of the area other than the external electrode is hollowed to the first face side (+Y′-axis direction). In the following description, the hollowed area is referred to as a hollow portion 127, and the unhollowed area is referred to as a convex portion 128.

The lid plate 110 includes a bonding face 112 bonded to the bonding face 122 of the base plate 120 using the encapsulating material 142 in the −Y′-axis side face and a hollow portion 111 hollowed from the bonding face 112 to the +Y′-axis side.

FIG. 2 is a cross-sectional view taken along a line II-II of FIG. 1. FIG. 2 illustrates a state that the piezoelectric device 100 is mounted on the mount board 150. The piezoelectric device 100 is formed by placing the piezoelectric vibrating piece 130 on the hollow portion 121 of the base plate 120 and bonding the bonding face 112 of the lid plate 110 to the bonding face 122 of the base plate 120 using the encapsulating material 142. The connection electrode 123 is formed in the hollow portion 121 of the base plate 120, and the connection electrode 123 and the extraction electrode 132 of the piezoelectric vibrating piece 130 are electrically connected to each other through the conductive adhesive 141. In addition, the penetrating electrode 124 that penetrates the base plate 120 electrically connects the connection electrode 123 and the mounting terminal 125. That is, the excitation electrode 131 of the piezoelectric vibrating piece 130 is electrically connected to the mounting terminal 125.

FIG. 2 illustrates a state that the piezoelectric device 100 is mounted on the mount board 150. A plurality of wiring electrodes are formed on the surface of the mount board 150. Hereinafter, the wiring electrode electrically connected to the piezoelectric device is referred to as a first wiring electrode 151, and the electrode not electrically connected to the piezoelectric device is referred to as a second wiring electrode 152. The external electrode of the piezoelectric device 100 is electrically connected to the first wiring electrode 151 of the mount board 150 using a solder 143. In addition, the second wiring electrode 152 is formed in the −Y′-axis side of the piezoelectric device 100 on the mount board 150. In some cases, the wiring electrode that is not electrically connected to the piezoelectric device, such as the second wiring electrode 152 of the mount board 150, overlaps with the piezoelectric device on the mount board in the Y′-axis direction for integration purposes. In the piezoelectric device 100, a height difference HA1 is provided between the excitation electrode 131 formed in the −Y-axis side face of the piezoelectric vibrating piece 130 and the second wiring electrode 152 on the mount board 150, and a height difference HA2 is provided between the second wiring electrode 152 and the connection electrode 123.

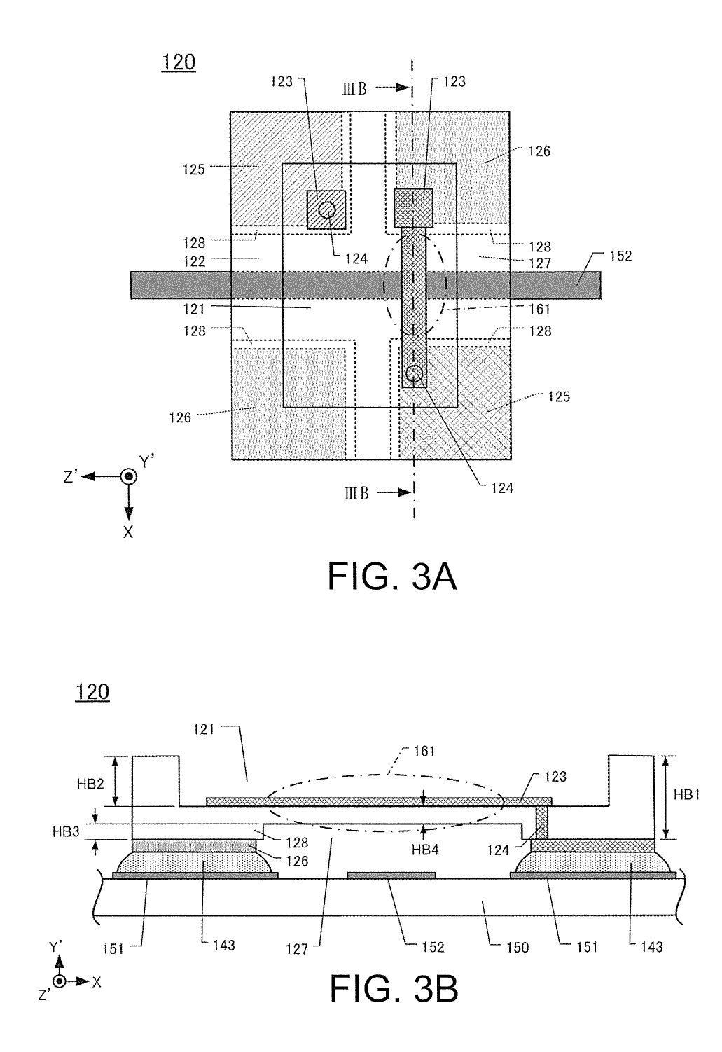

FIG. 3A is a top plan view illustrating the base plate 120. FIG. 3A illustrates the connection electrode 123 formed in the first face of the base plate 120, the mounting terminal 125 formed in the second face, and the ground terminal 126. The second wiring electrode 152 formed in the mount board 150 is illustrated as a reference. In the base plate 120, the convex portions 128 are formed in four corners of the second face, and the external electrode is formed in the −Y′-axis side face of the convex portion 128, respectively. In the base plate 120, the ground terminals 126 are formed in the +Z′-axis side of the +X-axis side and the −Z′-axis side of the −X-axis side, and the mounting terminals 125 are formed in the −Z′-axis side of the +X-axis side and the +Z′-axis side of the −X-axis side. In addition, in the base plate 120, each external electrode is formed with a gap from the hollow portion 127 in order not to make direct contact with the hollow portion 127. This is to prevent the solder 143 of the external electrode from crawling into the hollow portion 127 of the second face. In the base plate 120, as indicated by the area 161 surrounded by the one-dotted chain line in FIG. 3A, the second wiring electrode 152, the connection electrode 123, and the hollow portion 127 of the second face are formed to overlap with each other in the Y′-axis direction.

FIG. 3B is a cross-sectional view taken along a line IIIB-IIIB of FIG. 3A. A height of the entire base plate 120 in the Y′-axis direction is set to the height HB1, and a depth of the hollow portion 127 hollowed from the convex portion 128 to the +Y′-axis side is set to the depth HB3. In addition, a distance between the hollow portion 127 and the connection electrode 123 is set to the length HB4. The area 161 surrounded by the one-dotted chain line of FIG. 3B corresponds to the area 161 of FIG. 3A. In this area 161 of the connection electrode 123, the base plate 120 has a length HB4 in the Y′-axis direction.

The stray capacitance generated between the electrodes formed in the piezoelectric device and the second wiring electrode 152 is proportional to the dielectric constant between the electrodes. That is, if the dielectric constant between the electrodes is low, the generated stray capacitance is also low. In the piezoelectric device 100, as illustrated in FIG. 2, the base plate 120 is formed to be thin between the excitation electrode 131 or the connection electrode 123 and the second wiring electrode 152. Meanwhile, the air has a relative permittivity of 1.0006, quartz as a base material of crystal and glass has a relative permittivity of 3.5, and alumina used as the ceramic has a relative permittivity of 9.5. That is, the hollow portion 127 is formed in the second face of the base plate 120, and the base plate 120 is formed to be thin between the second wiring electrode 152 and the excitation electrode 131 or the connection electrode 123. Therefore, since the dielectric constant is lowered between the second wiring electrode 152 and the excitation electrode 131 or the connection electrode 123, the stray capacitance decreases. That is, the air having a low relative permittivity is preferably filled between the second face of the base plate 120 and the mount board 150. For this reason, it is preferable that nothing exist (there be a cavity) between the second face of the base plate 120 and the mount board 150.

If the base plate 120 is made of crystal or glass, the hollow portion 121 of the +Y′-axis side and the hollow portion 127 of the −Y′-axis side are formed by etching the base plate 120. For this reason, if the height HB2 is substantially equal to the height HB3 as illustrated in FIG. 3B, it is possible to form both the hollow portions through a single etching process, which is preferable.

### Second Embodiment

In the hollow portion formed in the second face of the base plate, various shapes may be formed. Hereinafter, a modification of the base plate will be described. In the following description, like reference numerals denote like elements as in the first embodiment, and description thereof will not be repeated.

<Configuration of Base Plate 220>

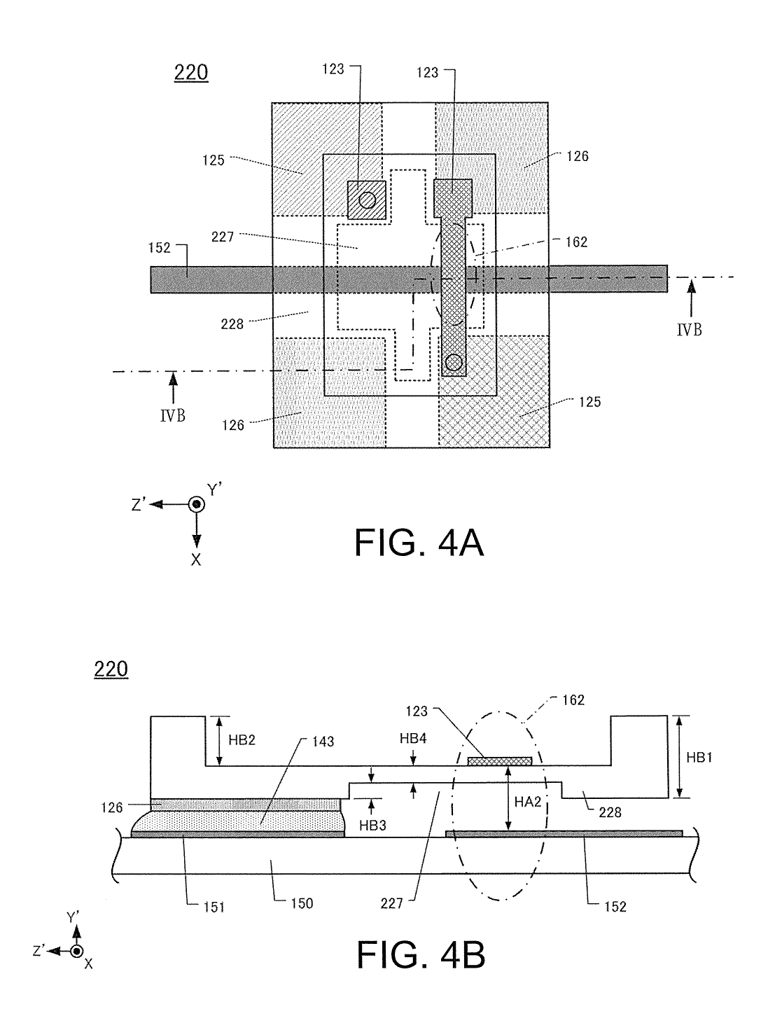

FIG. 4A is a top plan view illustrating the base plate 220. In FIG. 4A, the portion where elements are formed on the −Y′-axis side face (second face) is indicated by a dotted line, and the portion where elements are formed on the +Y′-axis side face (first face) is indicated by a solid line. In addition, the connection electrode 123 formed in the first face of the base plate 220 and the mounting terminal 125 and the ground terminal 126 formed in the second face are illustrated. Furthermore, in FIG. 4A, the second wiring electrode 152 formed in the mount board 150 is illustrated. In the second face of the base plate 220, the center of the second face is hollowed to the +Y′-axis side to form the hollow portion 227. In addition, the convex portion 228 is formed around the hollow portion 227. In the base plate 220, a part of the connection electrode 123, the second wiring electrode 152, and the hollow portion 227 are formed to overlap with each other in the area 162 surrounded by the one-dotted chain line in the Y′-axis direction.

FIG. 4B is a cross-sectional view taken along a line IVB-IVB of FIG. 4A. In FIG. 4B, the area corresponding to the area 162 of FIG. 4A is illustrated as the area 162 surrounded by the one-dotted chain line. In this area 162, the connection electrode 123, the second wiring electrode 152, and the hollow portion 227 are formed to overlap with each other in the Y′-axis direction. In this area 162, the thickness HB4 of the base plate 220 is formed to be thin. Therefore, similar to the base plate 120, the dielectric constant between the second wiring electrode 152 and the connection electrode 123 is lowered, and the stray capacitance generated in the piezoelectric device decreases.

In the base plate 220, the hollow portions 227 are formed in the center of the base plate 220 where the excitation electrode 131 is arranged and in the area where the connection electrode 123 is formed. For this reason, it is possible to decrease the stray capacitance generated between the connection electrode 123 or the excitation electrode 131 and the second wiring electrode 152. In addition, in the base plate 220, since the convex portion 228 is formed around the hollow portion 227 of the second face, it is possible to maintain a high impact resistance of the base plate 220.

<Configuration of Base Plate 320>

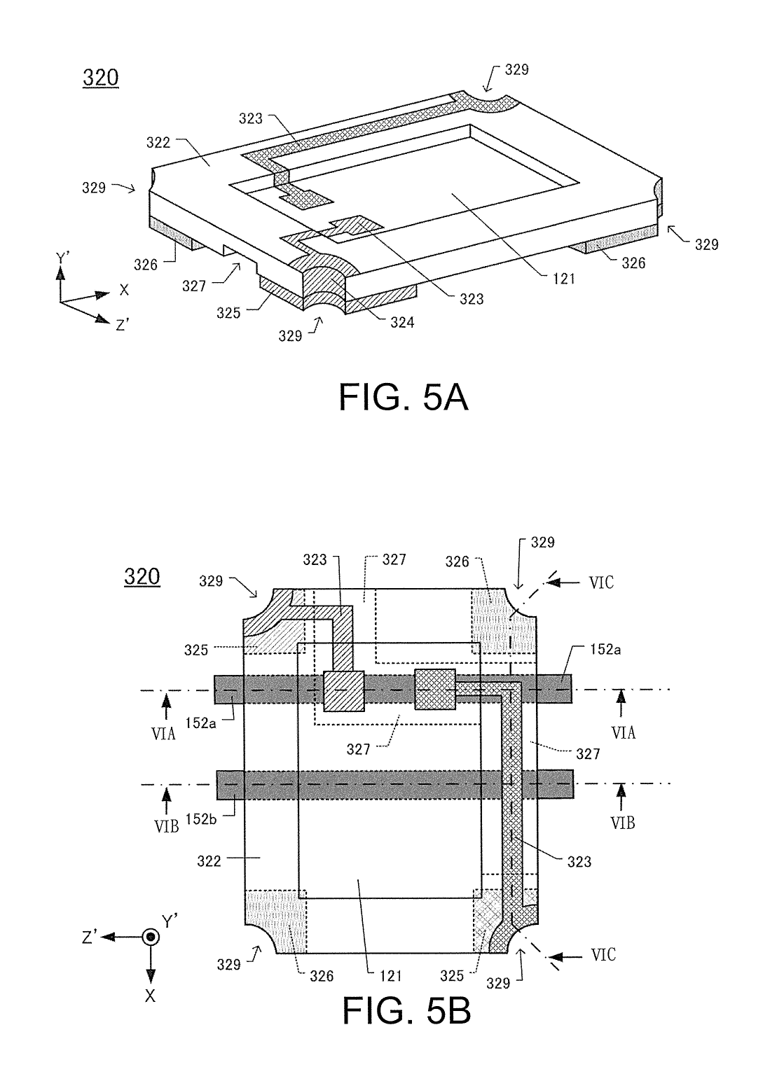

FIG. 5A is a perspective view illustrating the base plate 320. In the base plate 320, the hollow portion 121 is formed in the +Y′-axis side face (first face), and the bonding face 322 bonded to the lid plate 110 is formed around the hollow portion 121. In addition, the mounting terminal 325 or the ground terminal 326 is formed in four corners of the −Y′-axis side face (second face) of the base plate 320, and the hollow portion 327 hollowed in the +Y′-axis direction is formed in a part of the area other than the mounting terminal 325 or the ground terminal 326. The castellated portions 329 are formed in the lateral faces of four corners of the base plate 320, and the lateral electrode 324 is formed in the castellated portion 329. The connection electrode 323 formed in the hollow portion 121 and the bonding face 322 extends to the castellated portion 329 and is electrically connected to the lateral electrode 324. The lateral electrode 324 is electrically connected to the mounting terminal 325 or the ground terminal 326.

FIG. 5B is a top plan view illustrating the base plate 320. In FIG. 5B, the connection electrode 323 formed in the first face, the mounting terminal 325 formed in the second face, and the ground terminal 326 are illustrated. In addition, the second wiring electrode 152a and the second wiring electrode 152b formed in the mount board 150 are illustrated. The connection electrode 323 formed in the base plate 320 extends from the hollow portion 121 of the first face through the bonding face 322 to the castellated portion 329. The hollow portion 327 formed in the second face of the base plate 320 is formed along the connection electrode 323 formed in the first face. That is, the hollow portion 327 extends from the position biased to the +Z′-axis side from the lateral center of the −X-axis side of the base plate 320 to the +X-axis direction, extends from the position of the conductive adhesive 141 to the −Z′-axis direction, and extends from the bonding face 322 of the −Z′-axis side of the base plate 320 to the +X-axis direction.

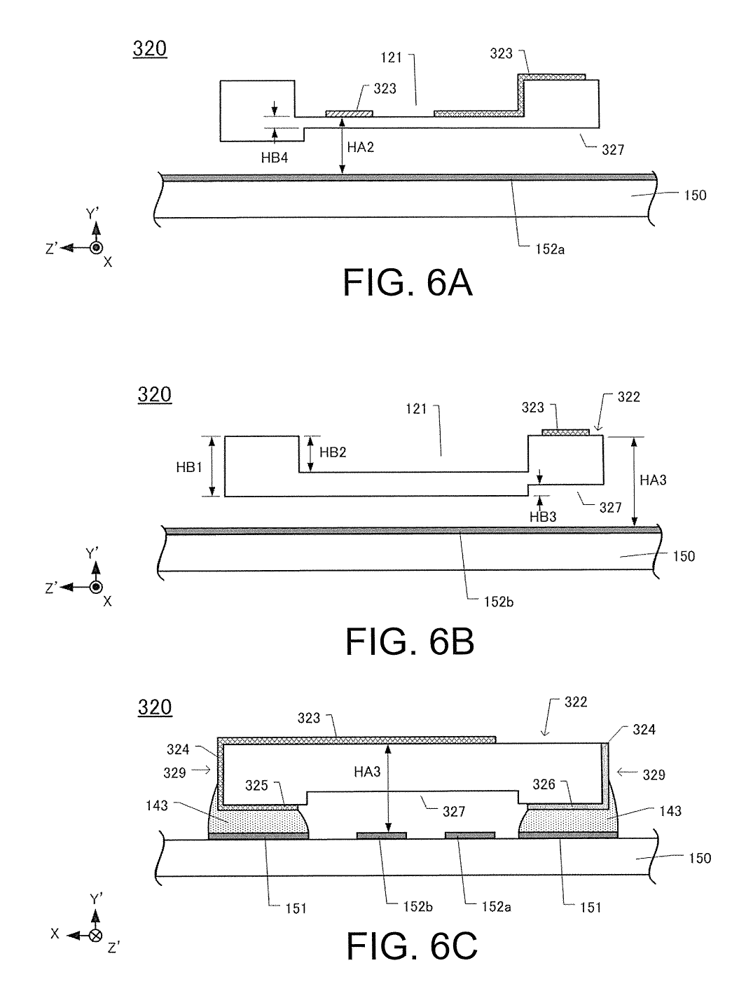

FIG. 6A is a cross-sectional view taken along a line VIA-VIA of FIG. 5B. The connection electrode 323 is formed in the hollow portion 121 of the base plate 320. A distance between the connection electrode 323 formed in the hollow portion 121 and the second wiring electrode 152a is set to the length HA2. In addition, the connection electrode 323, the hollow portion 327 of the second face, and the second connection electrode 152a are formed to overlap with each other in the Y′-axis direction.

FIG. 6B is a cross-sectional view taken along a line VIB-VIB of FIG. 5B. In the base plate 320, the connection electrode 323 is also formed in the bonding face 322. In this case, if a distance between the connection electrode 323 and the second wiring electrode 152b is set to HA3, the length HA3 is substantially longer than the length HA2. Since the stray capacitance is inversely proportional to the distance between electrodes, the stray capacitance decreases as the distance between electrodes increases. In addition, the hollow portion 327 of the second face is formed in the −Y′-axis side of the connection electrode 323.

FIG. 6C is a cross-sectional view taken along a line VIC-VIC of FIG. 5B. The connection electrode 323 extends on the bonding face 322 and is electrically connected to the lateral electrode 324 formed in the castellated portion 329. The second face of the bonding face 322 where the connection electrode 323 is formed is provided with a hollow portion 327 hollowed in the +Y′-axis direction.

In the base plate 320, since the connection electrode 323, the second wiring electrodes 152a and 152b, and the hollow portion 327 are formed to overlap with each other in the Y′-axis direction, the stray capacitance generated in the piezoelectric device decreases. In addition, the hollow portion 327 formed in the second face is limited to the −Y′-axis side of the connection electrode 323. Therefore, it is possible to suppress the thin thickness area of the base plate 320 to a minimum and maintain a high impact resistance of the base plate 320. Since the hollow portion 327 is formed along the connection electrode 323, the second wiring electrode, the connection electrode 323, and the hollow portion 327 overlap with each other in the Y′-axis direction regardless of how the second wiring electrode is wired. For this reason, it is possible to decrease the stray capacitance of the piezoelectric device without depending on the shape of the second wiring electrode.

### Third Embodiment

Description will now be made for a piezoelectric device 200 including the piezoelectric vibrating piece having the frame provided around the excitation portion where the excitation electrode is formed. In the following description, like reference numerals denote like elements as in the first and second embodiments, and description thereof will not be repeated.

<Configuration of Piezoelectric Device 200>

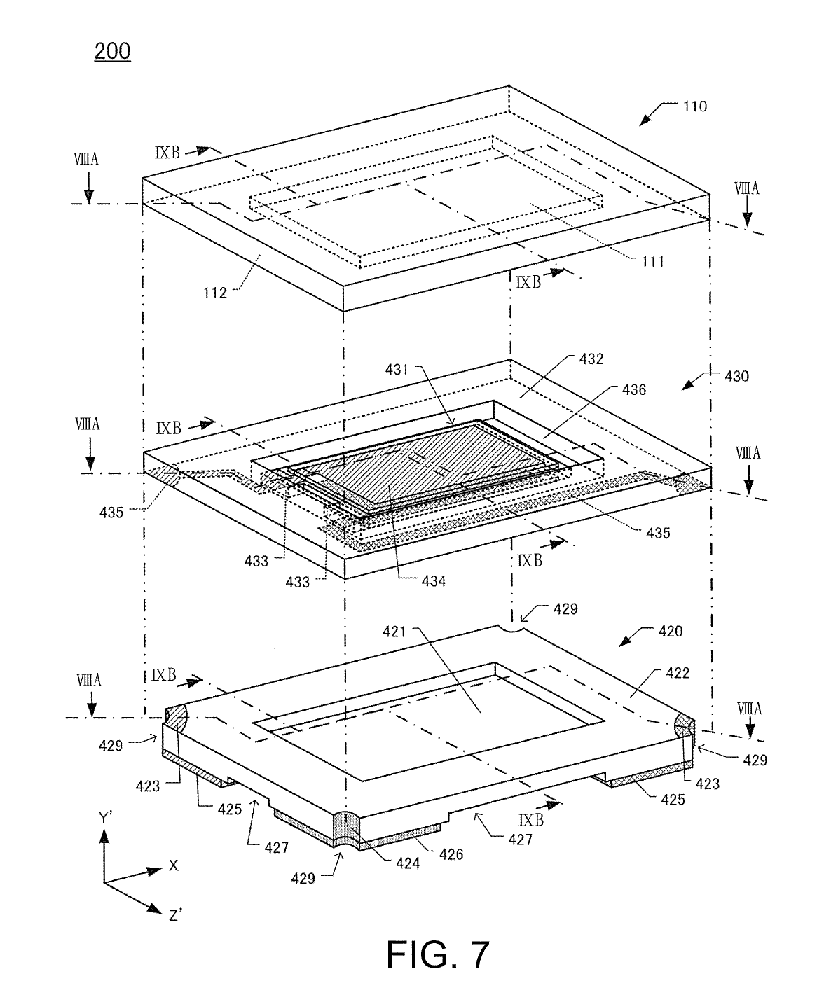

FIG. 7 is an exploded perspective view illustrating the piezoelectric device 200. The piezoelectric device 200 includes a lid plate 110, a base plate 420, and a piezoelectric vibrating piece 430. The piezoelectric vibrating piece 430 includes an excitation portion 431 where the excitation electrode 434 is formed, a frame 432 formed around the excitation portion 431, and a connecting portion 433 which connects the excitation portion 431 and the frame 432. The extraction electrode 435 is extracted from the excitation electrode 434 through the connecting portion 433 to the corner of the frame 432. In addition, a perforated trench 436 penetrating the piezoelectric vibrating piece 430 in the Y′-axis direction is formed in the area other than the connecting portion 433 between the excitation portion 431 and the frame 432.

In the base plate 420, a hollow portion 421 and a bonding face 422 surrounding the hollow portion 421 are formed in the +Y′-axis side face (first face). The base plate 420 is bonded to the −Y′-axis side face of the frame 432 of the piezoelectric vibrating piece 430 through the bonding face 422. The mounting terminal 425 or the ground terminal 426 is formed in four corners of the −Y′-axis side face (second face) of the base plate 420. In addition, the hollow portion 427 hollowed in the +Y′-axis direction is formed in a part of the area other than the mounting terminal 425 and the ground terminal 426 in the −Y′-axis side face. Furthermore, the castellated portions 429 are formed in lateral faces of four corners of the base plate 420. In the bonding face 422, the connection electrode 423 electrically connected to the extraction electrode 435 is formed around the castellated portions 429 in the +Z′-axis side of the +X-axis side and in the −Z′-axis side of the −X-axis side. The lateral electrode 424 is formed in the castellated portion 429, and the lateral electrode 424 electrically connects the connection electrode 423 and the mounting terminal 425.

The lid plate 110 is arranged in the +Y′-axis side of the piezoelectric vibrating piece 430, and the bonding face 112 is bonded to the +Y′-axis side face of the frame 432 of the piezoelectric vibrating piece 430.

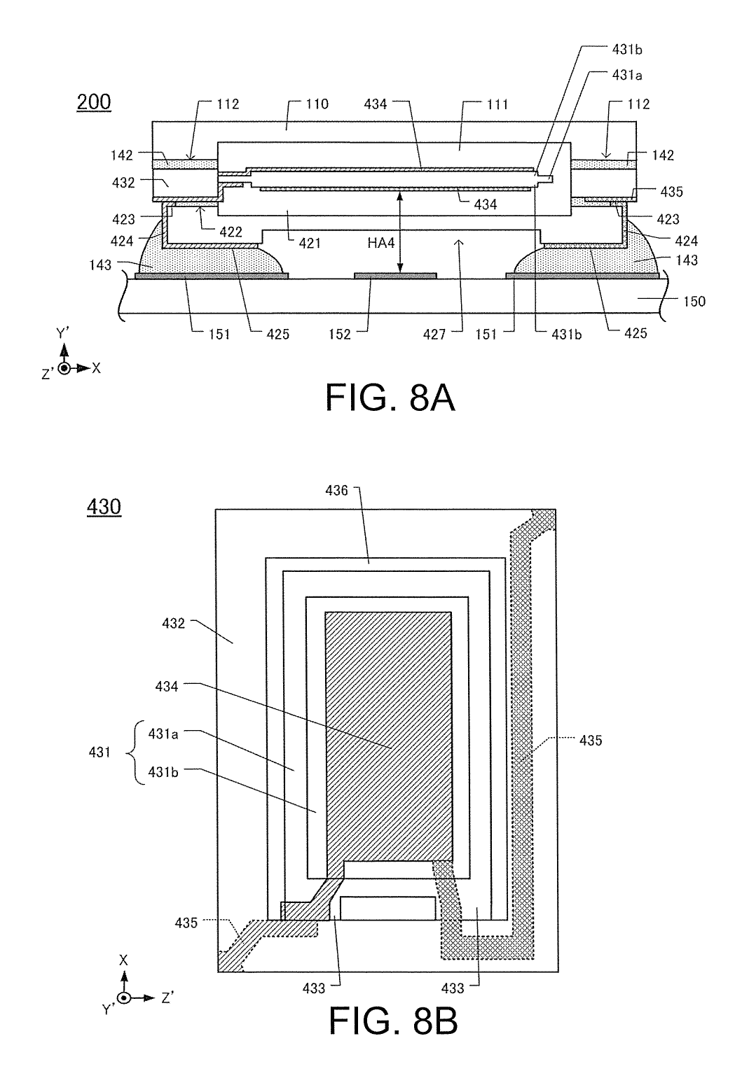

FIG. 8A is a cross-sectional view taken along a line VIIIA-VIIIA of FIG. 7. FIG. 8A illustrates the mount board 150 along with the cross-sectional view of the piezoelectric device 200. The base plate 420 is arranged in the −Y′-axis side of the piezoelectric vibrating piece 430, and the −Y′-axis side face of the frame 432 of the piezoelectric vibrating piece 430 is bonded to the bonding face 422 of the base plate 420 using the encapsulating material 142. In addition, the extraction electrode 435 is electrically connected to the connection electrode 423 of the base plate 420. The bonding face 112 of the lid plate 110 is bonded to the +Y′-axis side face of the frame 432 of the piezoelectric vibrating piece 430 using the encapsulating material 142.

The excitation electrode 434 of the piezoelectric vibrating piece 420 is electrically connected to the mounting terminal 425 through the extraction electrode 435, the connection electrode 423, and the lateral electrode 424. The mounting terminal 425 is electrically connected to the first wiring electrode 151 formed in the mount board 150 using a solder. The hollow portions are formed in each of the first and second faces of the base plate 420. In addition, a distance between the second wiring electrode 152 formed in the mount board 150 and the excitation electrode 434 formed in the −Y′-axis side face is set to the length HA4.

FIG. 8B is a top plan view illustrating the piezoelectric vibrating piece 430. The piezoelectric vibrating piece 430 includes an excitation portion 431 where the excitation electrode 434 is formed, a frame 432 formed around the excitation portion 431, and a connecting portion 433 which connects the frame 432 and the excitation portion 431. The connecting portion 433 is connected to the +Z′-axis side corner and the −Z′-axis side corner of the −X-axis side of the excitation portion 431 respectively, extends to the −X-axis direction therefrom, and is connected to the frame 432. The excitation portion 431 includes a mesa-structure area 431b where the excitation electrode 434 is formed and a circumferential area 431a formed around the mesa-structure area 431b. The mesa-structure area 431b projects from the circumferential area 431a to the +Y′-axis direction and the −Y′-axis direction. From the excitation electrode 434 formed in the +Y′-axis side, the extraction electrode 435 is extracted to the −Z′-axis side corner of the −X-axis side of the frame 432 through the +Y′-axis side face of the connecting portion 433 of the −Z′-axis side, the lateral face of the −Z′-axis side, and the −Y′-axis side face. In addition, from the excitation electrode 434 formed in the −Y′-axis side, the extraction electrode 435 is extracted to the +Z′-axis side corner of the +X-axis side of the frame 432 through the connecting portion 433 of the +Z′-axis side.

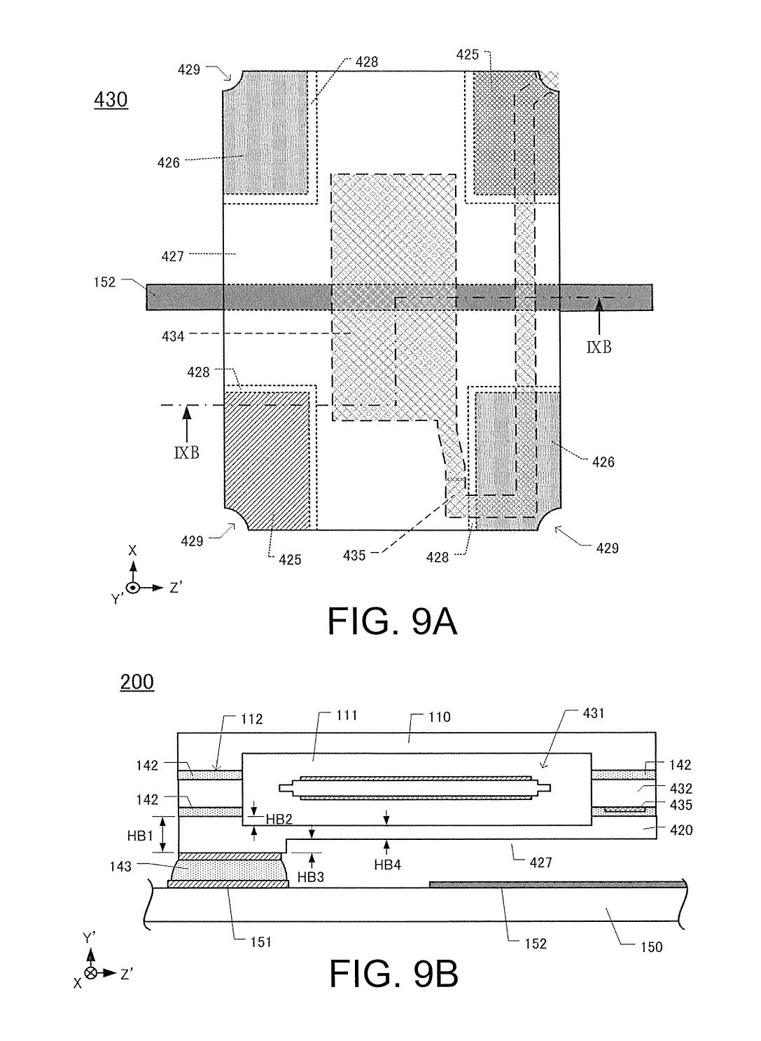

FIG. 9A is a top plan view illustrating the base plate 430. In FIG. 9A, the ground terminal 426 and the mounting terminal 425 formed in the second face of the base plate 430 are illustrated. In addition, the excitation electrode 434 formed in the −Y′-axis side face of the piezoelectric vibrating piece 130, the extraction electrode 435, and the second wiring electrode 152 formed in the mount board 150 are illustrated. The convex portions 428 are formed in four corners of the second face of the base plate 430, and the mounting terminal 425 or the ground terminal 426 is formed in the convex portion 428. In addition, the hollow portion 427 is formed in the area other than the convex portion 428 of the second face. For this reason, in the piezoelectric device 200, the excitation electrode 434 or the extraction electrode 435, the hollow portion 427 of the second face of the base plate 430, and the second wiring electrode 152 are formed to overlap with each other in the Y′-axis direction.

FIG. 9B is a cross-sectional view taken along a line IXB-IXB of FIG. 7. In the piezoelectric device 200, the excitation electrode 434 and the extraction electrode 435 of the piezoelectric vibrating piece 430 and the hollow portion 427 of the second face of the base plate 420 overlap with each other in the Y′-axis direction. For this reason, in the piezoelectric device 200, the thickness between the excitation electrode 434 or the extraction electrode 435 and the second wiring electrode 152 of the mount board 150 is formed to be thin, and the stray capacitance decreases.

In the piezoelectric device described above, the first face may be provided with a wiring electrode which electrically connects the extraction electrode and the external electrode, and the second face hollowed to the first face side may be formed in at least a part of an area between the excitation electrode or the wiring electrode and the mount board.

In the piezoelectric device described above, the first face of the base plate may have a hollow portion hollowed to the second face side, where the piezoelectric vibrating piece is placed, and a depth of the hollow portion may be substantially equal to a depth of the second face hollowed to the first face side.

In the piezoelectric device described above, the piezoelectric vibrating piece may have an excitation portion where the excitation electrode is formed and a frame formed around the excitation portion, and the frame may be bonded to the first face.

In the piezoelectric device described above, the frame may be provided with an extraction electrode, and the second face hollowed to the first face side may be formed in at least a part of an area between the excitation electrode or the extraction electrode formed in the frame and the mount board.

In the piezoelectric device described above, the first face of the base plate may have a bonding face bonded to the frame and a hollow portion hollowed to the second face side from the bonding face, and a depth of the hollow portion may be substantially equal to a depth of the second face hollowed to the first face side.

In the piezoelectric device described above, the base plate may be made of glass or piezoelectric material.

In the piezoelectric device according to this disclosure, is possible to decrease a stray capacitance generated from the mount board.

While best modes or embodiments of the invention have been described in detail hereinbefore, those skilled in the art will be appreciated that variations and changes may be made without departing from the scope or spirit of the present invention.

While description has been made by assuming that the piezoelectric vibrating piece is an AT-cut crystal vibrating piece in the aforementioned embodiments, the invention may be similarly applied to a BT-cut crystal vibrating in a thickness-shear mode. Furthermore, the piezoelectric vibrating piece described above may basically include various piezoelectric materials such as lithium tantalate, lithium niobate, or piezoelectric ceramic as well as the crystal material.

What is claimed is:

1. A piezoelectric device mounted on a mount board, comprising:
a piezoelectric vibrating piece having an excitation electrode and an extraction electrode extracted from the excitation electrode; and
a base plate made of an insulative material, the base plate having a first face where the piezoelectric vibrating piece is placed and a second face opposite to the first face, where an external electrode is provided,
wherein at least a part of an area other than the external electrode of the second face is hollowed to the first face side to form a cavity in the second face side for the mount board when the piezoelectric device is mounted on the mount board.

2. The piezoelectric device according to claim 1, wherein the first face is provided with a wiring electrode which electrically connects the extraction electrode and the external electrode, and
the second face hollowed to the first face side is formed in at least a part of an area between the excitation electrode or the wiring electrode and the mount board.

3. The piezoelectric device according to claim 1, wherein the first face of the base plate has a hollow portion hollowed to the second face side where the piezoelectric vibrating piece is placed, and
a depth of the hollow portion is substantially equal to a depth of the second face hollowed to the first face side.

4. The piezoelectric device according to claim 1, wherein the piezoelectric vibrating piece has an excitation portion where the excitation electrode is formed and a frame formed around the excitation portion, and
the frame is bonded to the first face.

5. The piezoelectric device according to claim 4, wherein the frame is provided with the extraction electrode, and
the second face hollowed to the first face side is formed in at least a part of an area between the excitation electrode or the extraction electrode formed in the frame and the mount board.

6. The piezoelectric device according to claim 4, wherein the first face of the base plate has a bonding face bonded to the frame and a hollow portion hollowed to the second face side from the bonding face, and
a depth of the hollow portion is substantially equal to a depth of the second face hollowed to the first face side.

7. The piezoelectric device according to claim 1, wherein the base plate is made of glass or piezoelectric material.
